(19) United States
(12) Patent Application Publication
(10) Pub. No.: US 2007/0172701 A1
(43) Pub. Date: Jul. 26, 2007

(54) Organic electroluminescent element

(75) Inventor: Hiroshi Tada, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/655,185

(22) Filed: Jan. 19, 2007

(30) Foreign Application Priority Data
Jan. 23, 2006 (JP) 2006-014297

(51) Int. Cl. H01L 51/54

(52) U.S. Cl. 428/690; 428/917; 313/504; 313/506; 257/E51.049; 257/E51.051

(57) ABSTRACT

The invention provides an organic electroluminescent element that has a pair of electrodes, and one or more organic compound layers disposed between the pair of electrodes and including at least one luminescent layer, and in which at least one layer of the organic compound layers includes at least one compound selected from a trispyrenylbenzene derivative and a dipyrenylbenzene derivative and at least one compound selected from a tetraphenylpyrene derivative and a tetraminopyrene derivative.

### CROSS-REFERENCE TO RELATED APPLICATION

This application claims priority under 35USC 119 from Japanese Patent Application No. 2006-14297, the disclosure of which is incorporated by reference herein.

### BACKGROUND OF THE INVENTION

1. Field of the Invention

The invention relates to an organic electroluminescent element that can emit light by converting electric energy into light.

2. Description of the Related Art

Today, research and development related to various display elements are actively proceeding, and among these, an organic electroluminescent element is attracting attention as a promising display element among them because light emission with high luminance can be obtained at low voltage.

An organic electroluminescent element is constituted by counter electrodes and an organic compound layer including a luminescent layer interposes therebetween, and uses light emission from an exciton produced by an electron injected from a cathode and a hole injected from an anode recombining in the luminescent layer, or uses light emission from an exciton of another molecule produced by energy transfer from the aforementioned exciton. For example, an organic luminescent element in which an organic thin film is formed by vapor deposition of an organic compound has proposed (for example, refer to “Applied Physics Letters”, vol. 51, p. 913, 1987).

Examples of technical problems in the organic electroluminescent element include improvement of luminous efficiency and emission luminance, reduction of power consumption, and improvement of driving durability, and various proposals have been made to solve such problems (for example, refer to Japanese Patent Application Laid-Open (JP-A) Nos. 2001-192651, 2001-118682, and 2003-234190).

However, the present situation is that further improvement of driving durability is demanded.

### SUMMARY OF THE INVENTION

The present invention has been made in consideration of the above-described circumstances and provides an organic electroluminescent element having a pair of electrodes, and one or more organic compound layers disposed between the pair of electrodes and which include at least one luminescent layer, and in which at least one layer of the organic compound layers include at least one compound selected from a trispyrenylbenzene derivative and a dipyrenylbenzene derivative and at least one compound selected from a tetraphenylpyrene derivative and a tetraminopyrene derivative.

The organic compound layer including the at least one compound selected from the group consisting of the trispyrenylbenzene derivative and the dipyrenylbenzene derivative and at least one compound selected from the group consisting of the tetraphenylpyrene derivative and the tetraminopyrene derivative is preferably a luminescent layer.

### DETAILED DESCRIPTION OF THE INVENTION

The organic electroluminescent element of the invention (sometimes appropriately referred to as an “organic EL element” or a “luminescent element” below) is explained in detail in the following.

The organic electroluminescent element of the invention is an organic electroluminescent element having a pair of electrodes, and one or more organic compound layers disposed between the pair of electrodes and which include at least one luminescent layer, and in which at least one layer of the organic compound layers include at least one compound selected from a trispyrenylbenzene derivative and a dipyrenylbenzene derivative and at least one compound selected from a tetraphenylpyrene derivative and a tetraminopyrene derivative.

The organic electroluminescent element of the invention can exhibit superior effects with respect to luminescent characteristics and driving durability due to the above-described configuration.

The organic electroluminescent element of the invention has one or more organic compound layers including at least one compound selected from the group consisting of the trispyrenylbenzene derivative and the dipyrenylbenzene derivative and at least one compound selected from the group consisting of the tetraphenylpyrene derivative and the tetraminopyrene derivative. The organic compound layer including these compounds is preferably a luminescent layer, and preferably includes the at least one compound selected from the group consisting of the trispyrenylbenzene derivative and the dipyrenylbenzene derivative as a host material and the at least one compound selected from the group of the tetraphenylpyrene derivative and the tetraminopyrene derivative as a dopant.

In the invention, a combination of the trispyrenylbenzene derivative and the tetraphenylpyrene derivative is particularly preferable.

In view of improvement in driving durability, the content ratio (mass ratio) of the trispyrenylbenzene derivative and/or the dipyrenylbenzene derivative to the tetraphenylpyrene derivative and/or the tetraminopyrene derivative in one layer of the organic compound layers is preferably from 100:0.1 to 100:30, more preferably from 100:0.5 to 100:20, and particularly preferably from 100:1 to 100:20.

The trispyrenylbenzene derivative and the dipyrenylbenzene derivative, and the tetraphenylpyrene derivative and the tetraminopyrene derivative applicable to the invention are explained in detail in the following.

### <Trispyrenylbenzene Derivative>

The trispyrenylbenzene derivative is preferably a compound presented by the following Formula (1).

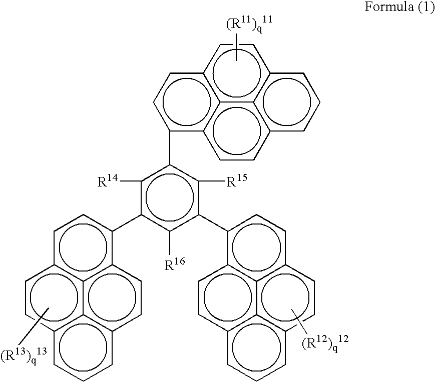

In Formula (1), R¹¹, R¹², and R¹³ represent a substituent. R¹⁴, R¹⁵, and R¹⁶ each independently represent a hydrogen atom or a substituent. q¹¹, q¹², and q¹³ each independently represent an integer from 0 to 9.

### Formula (1) is explained below.

In Formula (1), R¹¹, R¹², and R¹³ represent a substituent.

Examples of the substituent represented by R¹¹, R¹², and R¹³ include an alkyl group (preferably having 1 to 30 carbon atoms, more preferably having 1 to 20 carbon atoms, particularly preferably having 1 to 10 carbon atoms, and examples include methyl, ethyl, iso-propyl, tert-butyl, n-octyl, n-decyl, n-hexadecyl, cyclopropyl, cyclopentyl, and cyclohexyl), an alkenyl group (preferably having 2 to 30 carbon atoms, more preferably having 2 to 20 carbon atoms, particularly preferably having 2 to 10 carbon atoms, and examples include vinyl, allyl, 2-butenyl, and 3-pentenyl), an alkynyl group (preferably having 2 to 30 carbon atoms, more preferably having 2 to 20 carbon atoms, particularly preferably having 2 to 10 carbon atoms, and examples include propargyl and 3-pentynyl), an aryl group (preferably having 6 to 30 carbon atoms, more preferably having 6 to 20 carbon atoms, particularly preferably having 6 to 12 carbon atoms, and examples include phenyl, p-methylphenyl, naphthyl, and anthranyl), an amino group (preferably having 0 to 30 carbon atoms, more preferably having 0 to 20 carbon atoms, particularly preferably having 0 to 10 carbon atoms, and examples include amino, methylamino, dimethylamino, diethylamino, dibenzylamino, diphenylamino, and ditolylamino), an alkoxy group (preferably having 1 to 30 carbon atoms, more preferably having 1 to 20 carbon atoms, particularly preferably having 1 to 10 carbon atoms, and examples include metoxy, etoxy, butoxy, and 2-ethylhexyloxy), an aryloxy group (preferably having 6 to 30 carbon atoms, more preferably having 6 to 20 carbon atoms, particularly preferably having 6 to 12 carbon atoms, and examples include phenyloxy, 1-naphthyloxy, and 2-naphthyloxy), an heteroaryloxy group (preferably having 1 to 30 carbon atoms, more preferably having 1 to 20 carbon atoms, particularly preferably having 1 to 12 carbon atoms, and examples include pyridyloxy, pyradyloxy, pyrimidyloxy, and quinolyloxy), an acyl group (preferably having 1 to 30 carbon atoms, more preferably having 1 to 20 carbon atoms, particularly preferably having 1 to 12 carbon atoms, and examples include acetyl, benzoyl, formyl, and pivaloyl), an alkoxycarbonyl group (preferably having 2 to 30 carbon atoms, more preferably having 2 to 20 carbon atoms, particularly preferably having 2 to 12 carbon atoms, and examples include methoxycarbonyl and ethoxycarbonyl), an aryloxycarbonyl group (preferably having 7 to 30 carbon atoms, more preferably having 7 to 20 carbon atoms, particularly preferably having 7 to 12 carbon atoms, and example includes phenyloxycarbonyl), an acyloxy group (preferably having 2 to 30 carbon atoms, more preferably having 2 to 20 carbon atoms, particularly preferably having 2 to 10 carbon atoms, and examples include acetoxy and benzoyloxy), an acylamino group (preferably having 2 to 30 carbon atoms, more preferably having 2 to 20 carbon atoms, particularly preferably having 2 to 10 carbon atoms, and examples include acetylamino and benzoylamino), an alkoxycarbonylamino group (preferably having 2 to 30 carbon atoms, more preferably having 2 to 20 carbon atoms, particularly preferably having 2 to 12 carbon atoms, and example includes metoxycarbonylamino), an aryloxycarbonylamino group (preferably having 7 to 30 carbon atoms, more preferably having 7 to 20 carbon atoms, particularly preferably having 7 to 12 carbon atoms, and example includes phenyloxycarbonylamino), a sulfonylamino group (preferably having 1 to 30 carbon atoms, more preferably having 1 to 20 carbon atoms, particularly preferably having 1 to 12 carbon atoms, and examples include methanesulfonylamino and benzenesulfonylamino), a sulfamoyl group (preferably having 0 to 30 carbon atoms, more preferably having 0 to 20 carbon atoms, particularly preferably having 0 to 12 carbon atoms, and examples include sulfamoyl, methylsulfamoyl, dimethylsulfamoyl, and phenylsulfamoyl), a carbamoyl group (preferably having 1 to 30 carbon atoms, more preferably having 1 to 20 carbon atoms, particularly preferably having 1 to 12 carbon atoms, and examples include carbamoyl, methylcarbamoyl, dimethylcarbamoyl, and phenylcarbamoyl), an alkylthio group (preferably having 1 to 30 carbon atoms, more preferably having 1 to 20 carbon atoms, particularly preferably having 1 to 12 carbon atoms, and examples include methylthio and ethylthio), an arylthio group (preferably having 6 to 30 carbon atoms, more preferably having 6 to 20 carbon atoms, particularly preferably having 6 to 12 carbon atoms, and example includes phenylthio), a heteroarylthio group (preferably having 1 to 30 carbon atoms, more preferably having 1 to 20 carbon atoms, particularly preferably having 1 to 12 carbon atoms, and examples include pyridylthio, 2-benzimizolylthio, 2-benzoxazolylthio, and 2-benzthiazolylthio), a sulfonyl group (preferably having 1 to 30 carbon atoms, more preferably having 1 to 20 carbon atoms, particularly preferably having 1 to 12 carbon atoms, and examples include mesityl and tosyl), a sulfinyl group (preferably having 1 to 30 carbon atoms, more preferably having 1 to 20 carbon atoms, particularly preferably having 1 to 12 carbon atoms, and examples include methanesulfinyl and benzenesulfinyl), an ureido group (preferably having 1 to 30 carbon atoms, more preferably having 1 to 20 carbon atoms, particularly preferably having 1 to 12 carbon atoms, and examples include ureido, methylureido, and phenylureido), a phosphoric amide group (preferably having 1 to 30 carbon atoms, more preferably having 1 to 20 carbon atoms, particularly preferably having 1 to 12 carbon atoms, and examples include diethylphosphoric amide and phenylphosphoric amide), a hydroxy group, a mercapto group, a halogen atom (examples are a fluorine atom, a chlorine atom, a bromine atom, and an iodine atom), a cyano group, a sulfo group, a carboxyl group, a nitro group, a hydroxamic acid group, a sulfino group, a hydrazino group, an imino group, a heterocyclic group (preferably having 1 to 30 carbon atoms, more preferably having 1 to 12 carbon atoms, and examples of a hetero atom include a nitrogen atom, an oxygen atom, and a sulfur atom, and specifically imidazolyl, pyridyl, quinollyl, furyl, thienyl, piperidyl, morphoryno, benzoxazolyl, benzimidazolyl, benzthiazolyl, a carbazolyl group, and an azepinyl group), and a silyl group (preferably having 3 to 40 carbon atoms, more preferably having 3 to 30 carbon atoms, particularly preferably having 3 to 24 carbon atoms, and examples include trimethylsilyl and triphenylsilyl). These substituents may be further substituted.

The substituents represented by R¹¹, R¹², and R¹³ are preferably an alkyl group, an alkenyl group, an aryl group, a heteroaryl group, and an alkoxy group, more preferably an alkyl group and an aryl group, and still more preferably an aryl group.

q¹¹, q¹², and q¹³ each independently represent an integer from 0 to 9, preferably 0 to 3, more preferably 0 to 2, and still more preferably 0 or 1.

In Formula (1), R¹⁴, R¹⁵, and R¹⁶ each independently represent a hydrogen atom or a substituent. The substituents represented by R¹⁴, R¹⁵, and R¹⁶ are the same as the substituents represented by R¹¹, R¹², and R¹³ and the preferable ranges are also the same.

### <Dipyrenylbenzene Derivative>

The dipyrenylbenzene derivative is preferably a compound presented by the following Formula (2).

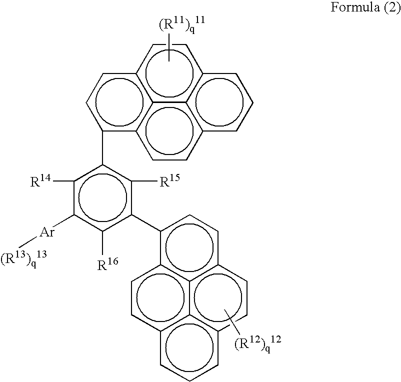

In Formula (2), R¹¹, R¹², and R¹³ represent a substituent. R¹⁴, R¹⁵, and R¹⁶ each independently represent a hydrogen atom or a substituent. Q¹¹, q¹², and q¹³ each independently represent an integer from 0 to 9. Ar represents an arylene group.

In Formula (2), the preferable ranges of the substituents represented by R¹¹, R¹², R¹³,
R¹⁴, R¹⁵, and R¹⁶, and the integers represented by q¹¹, q¹², and q¹³ are the same as those in Formula (1).

In Formula (2), the number of carbon atoms in the arylene group represented by Ar is preferably 6 to 30, more preferably 6 to 20, and further preferably 6 to 16. Examples of the arylene group include a phenylene group, a naphthylene group, an anthrylene group, a phenanthrenylene group, a pyrenylene group, a perynylene group, a fluorenylene group, a biphenylene group, a terphenylene group, a rubrenylene group, a chrysenylene group, triphenylenylene group, a benzoanthrylene group, a benzophenanthrenylene group, and a diphenylanthrylene group, and these arylene groups may have further substituents. The dipyrenylbenzene derivative which is applicable to the invention specifically includes the dipyrenylbenzene derivative described in paragraph number (0023) to (0062) of JP-A No. 2001-192651.

The trispyrenylbenzene derivative and the dipyrenylbenzene derivative in the invention may be a low molecular weight compound and may be an oligomer compound and a polymer compound (the weight-average molecular weight (expressed in terms of polystyrene) is preferably 1000 to 5000000, more preferably 2000 to 1000000, and still more preferably 3000 to 100000).

In the case of a polymer compound, a structure represented by Formula (1) or Formula (2) may be included in the polymer main chain and may be included in polymer side chains. In the case of a polymer compound, it may be a homo-polymer compound and may be a co-polymer.

The trispyrenylbenzene derivative and the dipyrenylbenzene derivative in the invention are preferably a low molecular weight compound. λₘₐₓ of a fluorescence spectrum (maximum luminescent wavelength) of the trispyrenylbenzene derivative and the dipyrenylbenzene derivative in the invention is preferably 400 to 500 nm, more preferably 400 to 480 nm, and still more preferably 400 to 460 nm.

Examples of the compounds of the trispyrenylbenzene derivative in the invention (1-1 to 1-6) and examples of the compounds of the dipyrenylbenzene derivative (2-1 to 2-2) are shown as follows. However, the invention is not limited to these in any way.

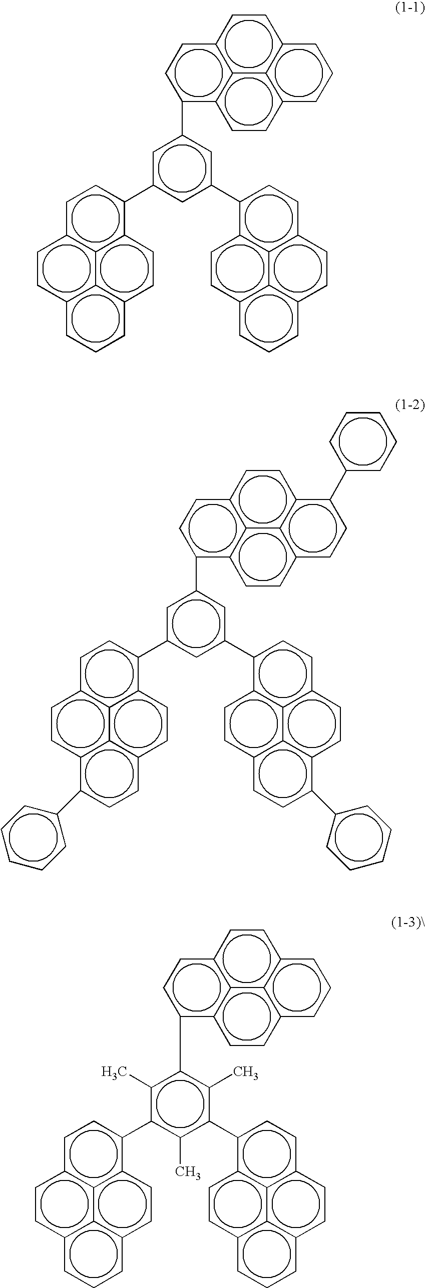

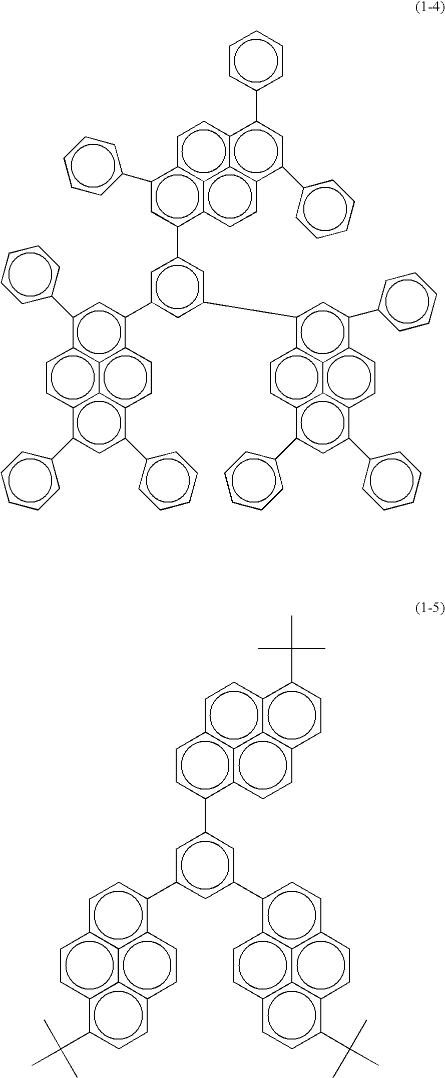

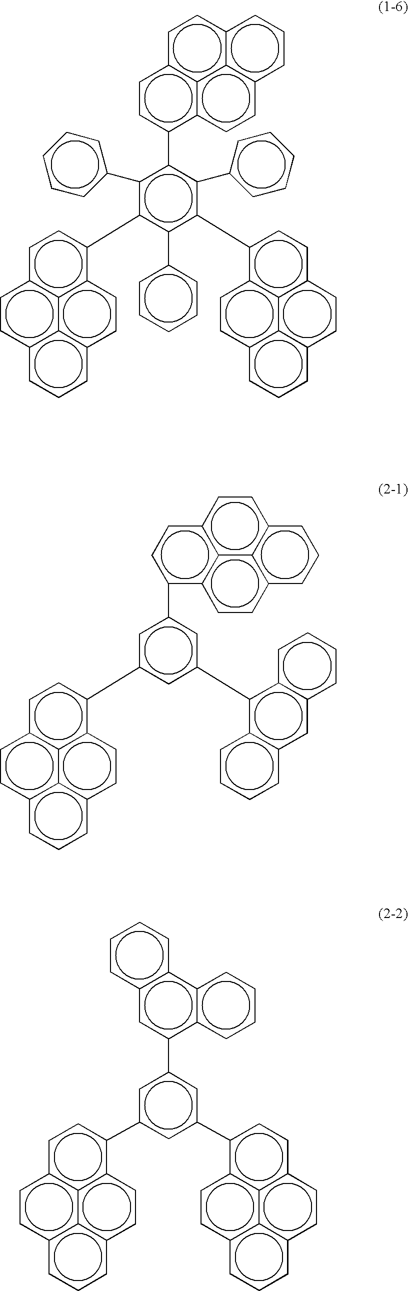

The trispyrenylbenzene derivative and the dipyrenylbenzene derivative in the invention can be synthesized with the method described in JP-A No. 2001-192651 etc. for example.

### <Tetraphenylpyrene Derivative>

The tetraphenylpyrene derivative is preferably a compound presented by the following Formulas (a) to (c).

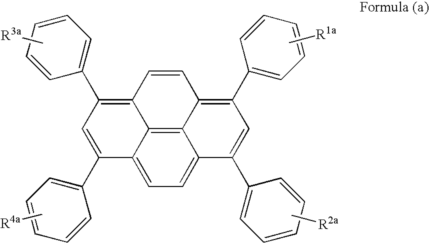

In Formula (a), R^{1a}, R^{2a}, R^{3a}, and R^{4a} each independently represent a hydrogen atom or a substituent. Examples of a substituent represented by R^{1a}, R^{2a}, R^{3a}, and R^{4a} include an alkyl group, a cycloalkyl group, and an aryl group. R^{1a}, R^{2a}, R^{3a}, and R^{4a} may be further substituted by a substituent.

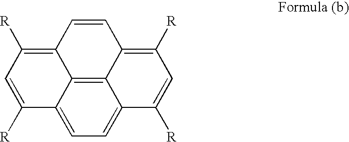

In Formula (b), R represents a group represented by the following formula.

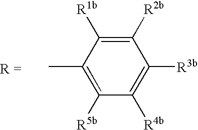

R^{1b} to R^{5b} each independently represent a hydrogen atom or a substituent. At least one of R^{1b} to R^{5b} is a substituted or unsubstituted phenyl group.

Substituents represented by R^{1b} to R^{5b} are preferably an alkyl group, an alkenyl group, an aryl group, a heteroaryl group, and an alkoxy group.

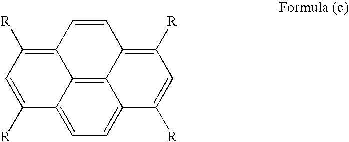

In Formula (c), R represents a group represented by the following formula.

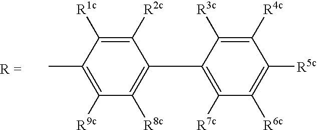

R^{1c} to R^{9c} each independently represent a hydrogen atom or a substituent. Substituents represented by R^{1c} to R^{9c} are preferably an alkyl group, an alkenyl group, an aryl group, a heteroaryl group, and an alkoxy group.

The tetraphenylpyrene derivative is preferably a compound presented by the following Formula (d).

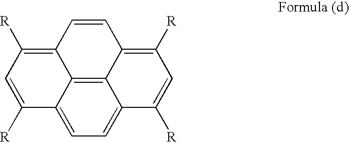

In Formula (d), R represents a group represented by the following formula.

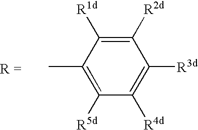

R^{1d} to R^{5d} each independently represent a hydrogen atom or a substituent. At least one of R^{1d} to R^{5d} is a group represented by the following formula. Substituents represented by R^{1d} to R^{5d} other than the group represented by the following formula are preferably an alkyl group, an alkenyl group, an aryl group, a heteroaryl group, and an alkoxy group.

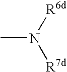

R^{6d} and R^{7d} each independently represent a hydrogen atom or a substituent.

Substituents represented by R^{6d} and R^{7d} are preferably an alkyl group, an alkenyl group, an aryl group, a heteroaryl group, and an alkoxy group.

### <Tetraminopyrene Derivative>

The tetraminopyrene derivative is preferably a compound presented by the following Formulas (e) and (f).

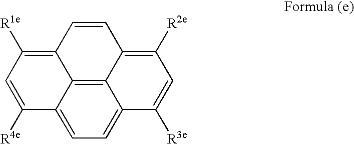

In Formula (e), R^{1e} to R^{4e} each independently represent a group represented by the following formula.

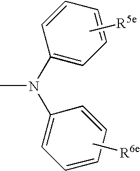

R^{5e} and R^{6e} each independently represent a hydrogen atom or an alkyl group.

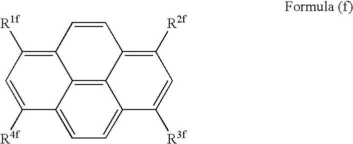

In Formula (f), R^{1f} to R^{4f} each independently represent a group represented by the following formula.

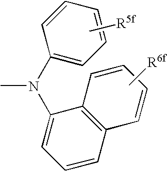

R^{5f} and R^{6f} each independently represent a hydrogen atom or an alkyl group. The tetraminopyrene derivative is preferably a compound presented by the following Formula (g).

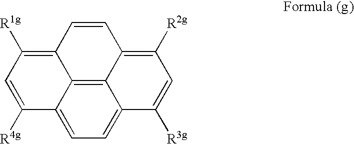

In Formula (g), R^{1g} to R^{4g} each independently represent a group represented by the following formula.

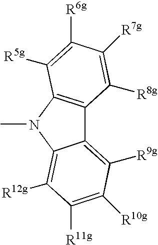

R^{5g} to R^{12g} each independently represent a hydrogen atom, an alkyl group, a substituted alkyl group, an aryl group, and a substituted aryl group (the aryl group indicates a group in which a monocyclic aromatic ring having a part which bonds to other chemical species or an aromatic ring which is a 4-membered ring or less is bonded, or a group having a condensed aromatic ring which is a 5-membered ring or less and the total number of carbon atoms, oxygen atoms, nitrogen atoms, and sulfur atoms is 50 or less).

Examples of the compounds of the tetraphenylpyrene derivative in the invention (3-1 to 3-3) and examples of the compounds of the tetraminopyrene derivative (4-1 to 4-3) are shown as follows. However, the invention is not limited to these in any way.

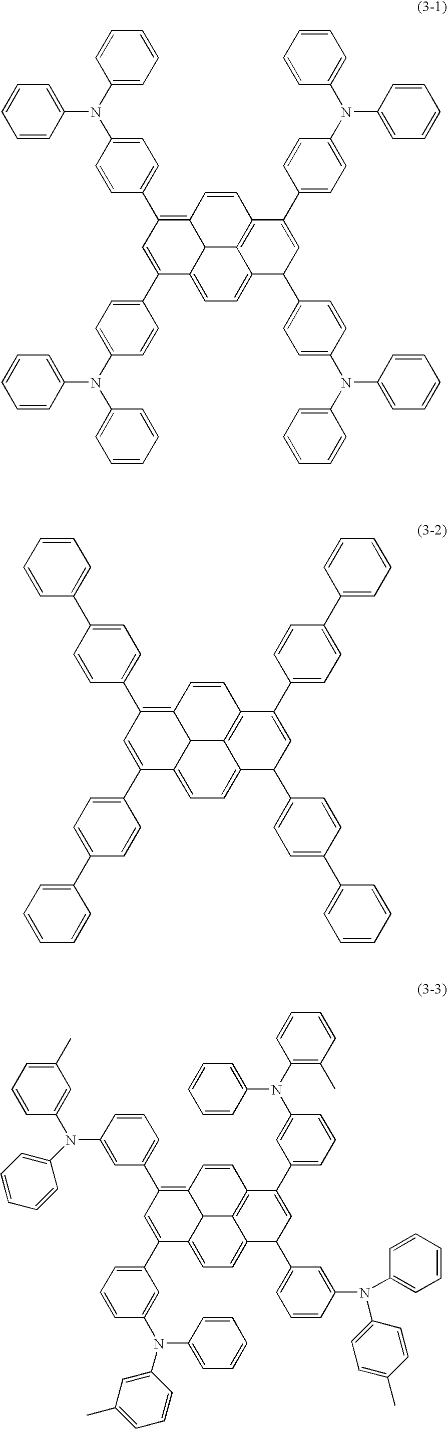

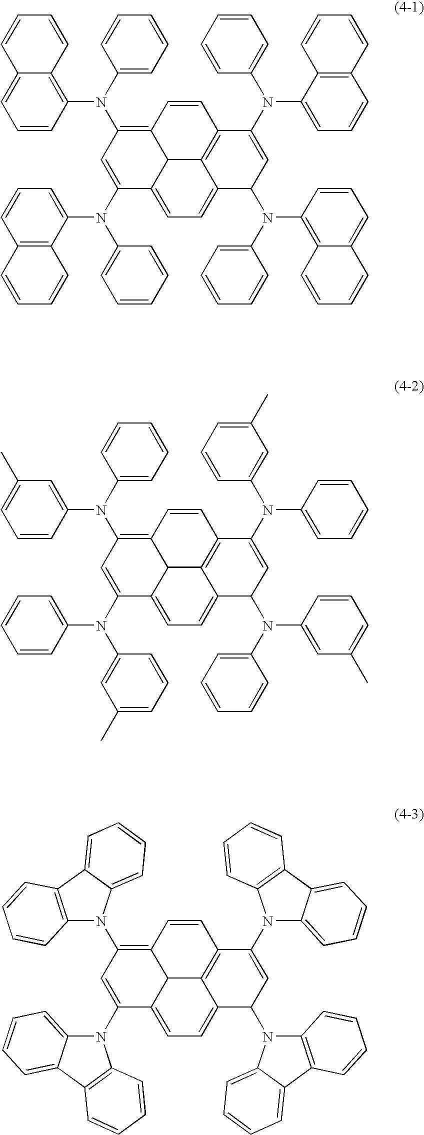

The configuration of the organic electroluminescent element of the invention is explained next.

The luminescent element of the invention is configured by having a cathode and anode and one or more organic compound layers including at least one layer of a luminescent layer between both electrodes. It is preferable that the cathode and the anode are formed on a substrate. From the nature of the luminescent element, at least one electrode of the anode and the cathode is preferably transparent. In the general case, the anode is transparent. The organic electroluminescent element of the invention may have a hole injection layer, a hole transport layer, an electron injection layer, an electron transport layer, and a protective layer, other than the luminescent layer, and each of these layers may be equipped with other functions. Various materials can be used in the formation of each layer.

The multilayered structure of the organic electroluminescent element is preferably a structure in which a hole transport layer, a luminescent layer, and an electron transport layer are successively layered from the anode side. The elements constituting the invention are explained in detail in the following.

### <Substrate>

The substrate that can be used in the invention is preferably a substrate that does not scatter and does not attenuate light emitting from the luminescent layer. Specific examples of the substrate include inorganic materials such as zirconia stabilized yttrium (YSZ) and glass, and organic materials such as polyester such as polyethylene terephthalate, polybutrylene phthalate, and polyethylene naphthalate, polystyrene, polycarbonate, polyether sulfone, polyarylate, polyimide, polycycloolrfin, a norbornene resin, and poly(chlorotrifluoroethylene).

In the case that glass is used as the substrate for example, a non-alkali glass is preferably used due to the quality of the material to decrease eluting ions from the glass. In the case that soda-lime glass is used, a substrate in which a barrier coat such as silica is applied is preferably used. In the case of an organic material, a substrate that is superior in heat resistance, dimensional stability, solvent resistance, electrical insulation property, and processability is preferable.

The form, the configuration, the size, etc. of the substrate are not particularly limited, and can be appropriately selected according to uses, objectives, etc. of the luminescent element. Generally, the form of the substrate is preferably a plate. The configuration of the substrate may be a mono-layered structure or a multi-layered structure, and may be formed with a single member and [or] may be formed with two or more members.

Although the substrate may be colorless and transparent or may be colored and transparent, it is preferably colorless and transparent in the respect that light emitting from a luminescent layer is not scattered or attenuated, etc. by the substrate.

The substrate can be equipped with a moisture permeation prevention layer (gas barrier layer) on the front surface or the rear surface.

Inorganic substances such as silicon nitride and silicon oxide are preferably used as the material of the moisture permeation prevention layer (gas barrier layer). The moisture permeation prevention layer (gas barrier layer) can be formed for example with a high frequency sputtering method, etc.

In the case that a thermoplastic substrate is used, the substrate may be also equipped with a hard coat layer, an under coat layer, etc. in addition as occasion demands.

### <Anode>

The form, the configuration, the size, etc. of the anode are not particularly limited as long as it has a function as an electrode supplying holes to the organic compound layer, and can be appropriately selected from the known electrode materials according to uses, objectives, etc. of the luminescent element. As described above, the anode is normally equipped as a transparent anode.

Examples of the material for the anode preferably include metals, alloys, metal oxides, conductive compounds, and mixtures thereof and a material having a work function of 4.0 eV or more is preferable. Specific examples of the anode material include conductive metal oxides such as tin oxide doped with antimony, fluorine, etc. (ATO, FTO), tin oxide, zinc oxide, indium oxide, indium tin oxide (ITO), and indium zinc oxide (IZO), metals such as gold, silver, chromium, and nickel, inorganic conductive substance such as mixtures and laminated materials of these metals and the conductive metal oxides, copper iodide, and copper sulfide, organic conductive materials such as polyaniline, polythiophene, and polypyrrole, and laminated materials of these and ITO. The conductive metal oxides are preferable among these and ITO is particularly preferable in the respect of productivity, high conductivity, transparency, etc.

The anode can be formed on the substrate according to a method appropriately selected from wet methods such as a printing method and a coating method, physical methods such as a vacuum deposition method, sputtering method, and an ion plating method, chemical methods such as CVD and plasma CVD methods, etc. considering suitability with the material constituting the anode. In the case that ITO is selected as the material for the anode for example, the formation of the anode can be performed according to a DC or high frequency sputtering method, a vacuum deposition method, an ion plating method, etc.

Although the position where the anode is formed is not particularly limited in the organic electroluminescent element of the invention and can be appropriately selected according to uses and objectives of the luminescent element, it is preferably formed on the substrate. In this case, the anode may be formed on the entirety of one of the surfaces or may be formed on a part of the surface.

The patterning when the anode is formed may be performed by chemical etching such as photolithography or may be performed by physical etching such as a method using a laser. It may also be performed by vacuum deposition, sputtering, etc. by superposing a mask or may be performed by a lift-off method or a printing method.

The thickness of the anode can be appropriately selected according to the material constituting the anode and cannot be stipulated absolutely. However, it is normally about 10 nm to 50 μm and preferably 50 nm to 20 μm.

The resistance of the anode is preferably 10³ Ω/sq. or less and more preferably 10² Ω/sq. or less. In the case that the anode is transparent, it may be colorless and transparent or it may be colored and transparent. The transmissivity is preferably 60% or more and more preferably 70% or more in order to emit luminescence from the transparent anode side. The transparent anode is described in “Toumei Dodenmaku no Shin-Tenkai” (“New Development of Transparent Conductive Film”) edited by Yutaka Sawada and published by CMC in 1999, and the items described here can be applied to the invention. In the case of a plastic substrate having a low heat resistance, ITO or IZO is used and a transparent anode formed at a low temperature of 150° C. or less is preferable.

### <Cathode>

The form, the configuration, the size, etc. of the cathode are not particularly limited as long as it has a function as an electrode injecting electrons to the organic compound layer, and can be appropriately selected from the known electrode materials according to uses and objectives of the luminescent element.

Examples of the material constituting the cathode include metals, alloys, metal oxides, electric conductive compounds, and mixtures thereof and a material having a work function of 4.5 eV or less is preferable. Specific examples include alkaline metals (for example, Li, Na, K, Cs, etc.), alkaline-earth metals (for example, Mg, Ca, etc.), gold, silver, lead, aluminum, a sodium-potassium alloy, a lithium-aluminum alloy, a magnesium-silver alloy, indium, and rare earth metals such as ytterbium. Although one kind of these materials may be used alone, two or more kinds of materials can be desirably used in combination in the respect of reconciling stability and electron injection performance.

Among these, alkaline metals and alkaline-earth metals are preferably used as a material constituting the cathode in the respect of the electron injection performance, and a material having aluminum as a main constituent is preferable in the respect of having superior storage stability. Materials having aluminum as a main constituent are aluminum alone, alloys of aluminum and 0.01 to 10% by mass of an alkaline metal or alkaline-earth metal, and mixtures thereof (for example, a lithium-aluminum alloy, a magnesium-aluminum alloy, etc.). The material for the cathode is described in JP-A Nos. 2-15595 and 5-121172, and the materials described in these documents can be applied to the invention.

The method of forming the cathode is not particularly limited and can be performed according to the known methods. For example, the cathode can be formed according to a method appropriately selected from wet methods such as a printing method and a coating method, physical methods such as a vacuum deposition method, sputtering method, and an ion plating method, chemical methods such as CVD and plasma CVD methods, etc. considering suitability with the material constituting the cathode. In the case that metals, etc. are selected as a material of the cathode, the formation of the cathode can be performed according to a sputtering method etc. in which one kind or two or more kinds is sputtered at same time or successively.

The patterning when the cathode is formed may be performed with chemical etching such as photolithography or may be performed with physical etching such as a method using a laser. It may be performed also with vacuum deposition, sputtering, etc. by superposing a mask or may be performed also with a lift-off method or a printing method.

In the present invention, the position where the cathode is formed is not particularly limited and it may be formed on an entire organic compound layer or may be formed on a part of it. A dielectric layer based on fluorides of alkaline metals or alkaline earth metals, oxides, etc. may be inserted with the thickness of 0.1 to 5 nm. This dielectric layer can be considered as one kind of the electron injection layer. The dielectric layer can be formed for example with a vacuum deposition method, a sputtering method, an ion-plating method, etc.

The thickness of the cathode can be appropriately selected according to the material constituting the cathode and cannot be stipulated absolutely. However, it is normally about 10 nm to 50 μm and preferably 50 nm to 1 μm.

The cathode may be transparent or may be opaque. The transparent cathode can be formed by forming a thin film of the cathode material at the thickness of 1 to 10 nm and then layering a transparent conductive material such as ITO and IZO.

### <Organic Compound Layer>

The organic electroluminescent element of the invention includes one or more organic compound layers including at least one layer of a luminescent layer. Examples of the layers beside the luminescent layer include a hole transport layer, an electron transport layer, a charge blocking layer, a hole injection layer, and an electron injection layer. The detail of these layers is described later.

### —Formation of Organic Compound Layer—

Each layer constituting the organic compound layer in the organic electroluminescent element of the invention can be formed desirably with any of the methods such as a dry film forming method such as a vapor deposition method and a sputtering method, a transfer method, and a printing method.

### —Luminescent Layer—

The luminescent layer is a layer having a function of receiving holes from the anode, the hole injection layer, or the hole transport layer, receiving electrons from the cathode, the electron injection layer, or the electron transport layer, and providing a stage of recombination of the hole and the electron to emit light. The luminescent layer may be one or may be two or more.

The luminescent layer in the invention is a layer including a luminescent material. In the invention, an embodiment in which a host material and a dopant as a luminescent material are included is preferable, and an embodiment in which the at least one compound selected from the group consisting of the trispyrenylbenzene derivative and the dipyrenylbenzene derivative is included as a host material and the at least one compound selected from the group consisting of the tetraphenylpyrene derivative and the tetraminopyrene derivative is included as a dopant is particularly preferable.

Examples of the materials that may be included in the luminescent layer include the trispyrenylbenzene derivative, the dipyrenylbenzene derivative, the tetraphenylpyrene derivative and the tetraminopyrene derivative, benzoxazole, benzimidazole, benzthiazole, styrylbenzene, polyphenyl, diphenylbutadiene, tetraphenylbutadiene, naphthalimide, coumalin, perylene, perynone, oxaziazole, aldazine, pyralizine, cyclopentadiene, bisstyrylanthracene, quinacridone, pyrrolopyridine, thiazolopyridine, styrylamine, aromatic dimethylidine compounds, various metal complexes represented by metal complexes of 8-quinolinol and rare earth complexes, polymer compounds such as polythiofen, polyphenylene, polyphenylenevinylene, organic silane, transition metal complexes represented by a iridium trisphenylpyridine complex and a platinum porphyrin complex, and derivatives thereof.

Although the thickness of the luminescent layer is not particularly limited, normally, it is preferably 1 nm to 500 nm, more preferably 5 nm to 200 nm, and further preferably 10 nm to 100 nm.

### —Hole Injection Layer and Hole Transport Layer—

The hole injection layer and the hole transport layer have a function of receiving a hole from the anode or the anode side and transporting it to the cathode side. It is possible to promote the transportation of the holes by equipping the hole transport layer in the anode side of the luminescent layer. It is also possible to promote the injection of the holes from the anode by equipping the hole injection layer in the anode side of the hole transport layer. The hole injection layer and the hole transport layer preferably include a carbazole derivative, a triazole derivative, an oxazole derivative, an oxaziazole derivative, an imidazole derivative, a polyarylalkane derivative, a pyrazolin derivative, a pyrazolone derivative, a phenylenediamine derivative, an arylamine derivative, an amino substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidine-based compound, a porphyrin-based compound, an organic silane derivative, and a carbon.

The thicknesses of the hole injection layer and the hole transport layer are preferably 50 nm or less each in the respect of reducing the driving voltage. The thickness of the hole transport layer is preferably 5 to 50 nm and more preferably 10 to 40 nm. The thickness of the hole injection layer is preferably 0.5 to 50 nm and more preferably 1 to 40 nm. The hole injection layer and the hole transport layer may have a single layered structure consisting of one kind or two or more kinds of the above-described materials, or may have a multi-layered structure consisting of a plurality of layers of the same composition or different kinds of compositions.

The electron-accepting dopant can be included in the hole injection layer or the hole transport layer in the organic EL element of the invention. Inorganic compounds and organic compounds may be used as the electron-accepting dopant to be introduced in the hole injection layer or the hole transport layer as long as the compound has the characteristic of oxidizing an organic compound and acting as an electron accepter.

In the case that the electron-accepting dopant is an inorganic compound, specific examples include halide metals such as secondary iron chloride, aluminum chloride, gallium chloride, indium chloride, and antimony pentachloride, and metal oxides such as vanadium pentaoxide and molybdenum trioxide.

In the case that the electron-accepting dopant is an organic compound, compounds having a nitro group, halogen, a cyano group, and a trifluoromethyl group as a substituent, quinine-based compounds, acid anhydride-based compounds, fullerene, etc. can be preferably used.

In addition, compounds described in JP-ANos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643, etc. can be preferably used as the electron-accepting dopant. These electron-accepting dopants may be used alone or two or more kinds thereof may be used. The amount of the electron-accepting dopant used differs with the types of the material. However, it is preferably 0.01% by mass to 50% by mass to the material constituting the hole transport layer or the hole injection layer, more preferably 0.05% by mass to 20% by mass, and particularly preferably 0.1% by mass to 10% by mass.

### —Electron Injection Layer and Electron Transport Layer—

The electron injection layer and the electron transport layer have a function of receiving an electron from the cathode or the cathode side and transporting it to the anode side. It is possible to promote the transportation of the electrons by equipping the electron transport layer in the cathode side of the luminescent layer. It is also possible to promote the injection of the electrons from the cathode by equipping the electron injection layer in the cathode side of the electron transport layer.

The electron injection layer and the electron transport layer are preferably layers including a triazole derivative, an oxazole derivative, an oxadiazole derivative, an imidazole derivative, a fluorenone derivative, an anthraquinodimetane derivative, an anthrone derivative, a diphenylquinone derivative, a thiopyrandioxide derivative, a carbodiimide derivative, a fluorennylidene methane derivative, a distyrylpyrazine derivative, an aromatic ring tetracarboxylic anhydride such as naphthalene and perylene, a phthalocyanine derivative, various metal complexes represented by metal complexes of a 8-quinolinol derivative, a metal phthalocyanine, metal complexes having benzoxazole and benzothiazole as a ligand, an organic silane derivative, etc.

The thicknesses of the electron injection layer and the electron transport layer are preferably 50 nm or less each in the respect of reducing the driving voltage. The thicknesses of the electron injection layer and the electron transport layer are preferably 5 to 50 nm and more preferably 10 to 50 nm.

The electron injection layer and the electron transport layer may have a single layered structure consisting of one kind or two or more kinds of the above-described materials, or may have a multi-layered structure consisting of a plurality of layers of the same composition or different kinds of compositions.

The electron-donating dopant can be included in the electron injection layer or the electron transport layer in the organic EL element of the invention. Alkaline metals such as Li, alkaline-earth metals such as Mg, transition metals including rare-earth metals, and reductive organic compounds, etc. can be preferably used as the electron-donating dopant to be introduced in the electron injection layer or the electron transport layer as long as the compound has the characteristic of reducing an organic compound acting as an electron donor. Metals particularly having a work function of 4.2 eV or less can be preferably used and examples include Li, Na, K, Be, Mg, Ca, Sr, Ba, Y, Cs, La, Sm, Gd, and Yb. Examples of the reductive organic compounds include nitrogen-containing compounds, sulfur-containing compounds, and phosphorus-containing compounds.

In addition, compounds described in JP-A Nos. 6-212153, 2000-196140, 2003-68468, 2003-229278, 2004-342614, etc. can be preferably used as the electron-donating dopant. These electron-donating dopants may be used alone or two or more kinds may be used. The amount of the electron-donating dopant used differs with the types of the material. However, it is preferably 0.1% by mass to 99% by mass to the material constituting the electron transport layer or the electron injection layer, more preferably 1.0% by mass to 80% by mass, and particularly preferably 2.0% by mass to 70% by mass.

### —Hole Blocking Layer—

In the invention, a hole blocking layer including a compound represented by the following Formula (A) is preferably equipped in the cathode side of the luminescent layer.

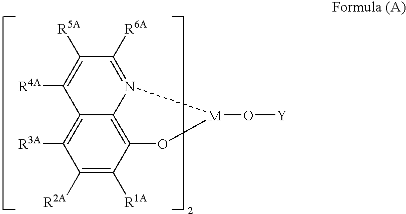

In Formula (A), at least one of R^{1A} to R^{6A} represent a substituent and the remainder represents hydrogen atoms; M represents aluminum, gallium, and indium; and Y represents an aromatic group which may have a substituent or a silyl group.

The silyl groups represented by Y are preferably an alkylsilyl group (preferably having 3 to 40 carbon atoms, more preferably having 3 to 30 carbon atoms, particularly preferably having 3 to 24 carbon atoms, and examples include trimethylsilyl and dimethyl-tert-buthylsilyl), an arylsilyl group (preferably having 18 to 60 carbon atoms, more preferably having 18 to 50 carbon atoms, particularly preferably having 18 to 40 carbon atoms, and examples include triphenylsilyl, diphenyl-1-naphthylsilyl, and diphenyl-2-naphthylsilyl), an alkylarylsilyl group (preferably having 15 to 60 carbon atoms, more preferably having 15 to 50 carbon atoms, particularly preferably having 15 to 40 carbon atoms, and examples include dimethylphenylsilyl, diphenylmethylsilyl, diphenyl-1-naphthylsilyl, and diphenyl-2-naphthylsilyl), and an aromatic heterocyclic substituted silyl group (preferably having 3 to 60 carbon atoms, more preferably having 3 to 50 carbon atoms, particularly preferably having 3 to 40 carbon atoms, and examples include tripridylsilyl and diphenylpyridylsilyl), more preferably an arylsilyl group, further preferably a triphenylsilyl group having 18 to 60 carbon atoms, and particularly preferably a triphenylsilyl group which may have a substituent.

The aromatic group represented by Y may be any of an aromatic hydrocarbon group and an aromatic heterocyclic group. The aromatic hydrocarbon group represented by Y preferably has 6 to 30 carbon atoms, more preferably 6 to 20 carbon atoms, particularly preferably 6 to 12 carbon atoms, and examples include phenyl, 4-methyl-phenyl, 4-cyano-phenyl, 1-naphthyl, 2-naphthyl, 1-anthranyl, 1-phenanthryl, and 1-pyrenyl.

The aromatic heterocyclic group represented by Y preferably has 1 to 30 carbon atoms, more preferably 1 to 20 carbon atoms, particularly preferably 1 to 12 carbon atoms, and examples of a hetero atom include a nitrogen atom, an oxygen atom, and a sulfur atom. Specific examples of the aromatic heterocyclic group represented by Y include imidazollyl, pyridyl, quinollyl, quinoxalyl, furil, thienyl, pyrazolyl, benzoxazolyl, benzimidazolyl, benzthiazolyl, a carbazolyl group, and an azepinyl group.

The silyl group and the aromatic group represented by Y may have a substituent, and examples of the substituent include an alkyl group (preferably having 1 to 30 carbon atoms, more preferably having 1 to 20 carbon atoms, particularly preferably having 1 to 10 carbon atoms, and examples include methyl, ethyl, iso-propyl, tert-butyl, n-octyl, n-decyl, n-hexadecyl, cyclopropyl, cyclopentyl, and cyclohexyl), an alkenyl group (preferably having 2 to 30 carbon atoms, more preferably having 2 to 20 carbon atoms, particularly preferably having 2 to 10 carbon atoms, and examples include vinyl, allyl, 2-butenyl, and 3-pentenyl), an alkynyl group (preferably having 2 to 30 carbon atoms, more preferably having 2 to 20 carbon atoms, particularly preferably having 2 to 10 carbon atoms, and examples include propargyl and 3-pentynyl), an aryl group (preferably having 6 to 30 carbon atoms, more preferably having 6 to 20 carbon atoms, particularly preferably having 6 to 12 carbon atoms, and examples include phenyl, p-methylphenyl, naphthyl, and anthranyl), an amino group (preferably having 0 to 30 carbon atoms, more preferably having 0 to 20 carbon atoms, particularly preferably having 0 to 10 carbon atoms, and examples include amino, methylamino, dimethylamino, diethylamino, dibenzylamino, diphenylamino, and ditolylamino), an alkoxy group (preferably having 1 to 30 carbon atoms, more preferably having 1 to 20 carbon atoms, particularly preferably having 1 to 10 carbon atoms, and examples include metoxy, etoxy, butoxy, and 2-ethylhexyloxy), an aryloxy group (preferably having 6 to 30 carbon atoms, more preferably having 6 to 20 carbon atoms, particularly preferably having 6 to 12 carbon atoms, and examples include phenyloxy, 1-naphthyloxy, and 2-naphthyloxy), an heterocycloxy group (preferably having 1 to 30 carbon atoms, more preferably having 1 to 20 carbon atoms, particularly preferably having 1 to 12 carbon atoms, and examples include pyridyloxy, pyradyloxy, pyrimidyloxy, and quinolyloxy), an acyl group (preferably having 1 to 30 carbon atoms, more preferably having 1 to 20 carbon atoms, particularly preferably having 1 to 12 carbon atoms, and examples include acetyl, benzoyl, formyl, and pivaloyl), an alkoxycarbonyl group (preferably having 2 to 30 carbon atoms, more preferably having 2 to 20 carbon atoms, particularly preferably having 2 to 12 carbon atoms, and examples include metoxycarbonyl and etoxycarbonyl), an aryloxycarbonyl group (preferably having 7 to 30 carbon atoms, more preferably having 7 to 20 carbon atoms, particularly preferably having 7 to 12 carbon atoms, and example includes phenyloxycarbonyl), an acyloxy group (preferably having 2 to 30 carbon atoms, more preferably having 2 to 20 carbon atoms, particularly preferably having 2 to 10 carbon atoms, and examples include acetoxy and benzoyloxy), an acylamino group (preferably having 2 to 30 carbon atoms, more preferably having 2 to 20 carbon atoms, particularly preferably having 2 to 10 carbon atoms, and examples include acetylamino and benzoylamino), an alkoxycarbonylamino group (preferably having 2 to 30 carbon atoms, more preferably having 2 to 20 carbon atoms, particularly preferably having 2 to 12 carbon atoms, and example includes metoxycarbonylamino), an aryloxycarbonylamino group (preferably having 7 to 30 carbon atoms, more preferably having 7 to 20 carbon atoms, particularly preferably having 7 to 12 carbon atoms, and example includes phenyloxycarbonylamino), a sulfonylamino group (preferably having 1 to 30 carbon atoms, more preferably having 1 to 20 carbon atoms, particularly preferably having 1 to 12 carbon atoms, and examples include methanesulfonylamino and benzenesulfonylamino), a sulfamoyl group (preferably having 0 to 30 carbon atoms, more preferably having 0 to 20 carbon atoms, particularly preferably having 0 to 12 carbon atoms, and examples include sulfamoyl, methylsulfamoyl, dimethylsulfamoyl, and phenylsulfamoyl), a carbamoyl group (preferably having 1 to 30 carbon atoms, more preferably having 1 to 20 carbon atoms, particularly preferably having 1 to 12 carbon atoms, and examples include carbamoyl, methylcarbamoyl, diethylcarbamoyl, and phenylcarbamoyl), an alkylthio group (preferably having 1 to 30 carbon atoms, more preferably having 1 to 20 carbon atoms, particularly preferably having 1 to 12 carbon atoms, and examples include methylthio and ethylthio), an arylthio group (preferably having 6 to 30 carbon atoms, more preferably having 6 to 20 carbon atoms, particularly preferably having 6 to 12 carbon atoms, and example includes phenylthio), a heterocyclthio group (preferably having 1 to 30 carbon atoms, more preferably having 1 to 20 carbon atoms, particularly preferably having 1 to 12 carbon atoms, and examples include pyridylthio, 2-benzimizolylthio, 2-benzoxazolylthio, and 2-benzthiazolylthio), a sulfonyl group (preferably having 1 to 30 carbon atoms, more preferably having 1 to 20 carbon atoms, particularly preferably having 1 to 12 carbon atoms, and examples include mesyl and tosyl), a sulfinyl group (preferably having 1 to 30 carbon atoms, more preferably having 1 to 20 carbon atoms, particularly preferably having 1 to 12 carbon atoms, and examples include methanesulfinyl and benzenesulfinyl), an ureido group (preferably having 1 to 30 carbon atoms, more preferably having 1 to 20 carbon atoms, particularly preferably having 1 to 12 carbon atoms, and examples include ureido, methylureido, and phenylureido), a phosphoric amide group (preferably having 1 to 30 carbon atoms, more preferably having 1 to 20 carbon atoms, particularly preferably having 1 to 12 carbon atoms, and examples include diethylphosphoric amide and phenylphosphoric amide), a hydroxy group, a melcapto group, a halogen atom (examples are a fluorine atom, a chlorine atom, a bromine atom, and an iodine atom), a cyano group, a sulfo group, a carboxyl group, a nitro group, a hydroxamic acid group, a sulfino group, a hydrazine group, an imino group, a heterocyclic group (preferably having 1 to 30 carbon atoms, more preferably having 1 to 12 carbon atoms, and examples of a hetercyclic atom include a nitrogen atom, an oxygen atom, and a sulfur atom, and specifically imidazolyl, pyridyl, quinolyl, furyl, thienyl, piperidyl, morphoryno, benzoxazolyl, benzimidazolyl, benzthiazolyl, a carbazolyl group, and an azepinyl group), a silyl group (preferably having 3 to 40 carbon atoms, more preferably having 3 to 30 carbon atoms, particularly preferably having 3 to 24 carbon atoms, and examples include trimethylsilyl and triphenylsilyl), and a silyloxy group (preferably having 3 to 40 carbon atoms, more preferably having 3 to 30 carbon atoms, particularly preferably having 3 to 24 carbon atoms, and examples include trimethylsilyloxy and triphenylsilyloxy). These substituents may be substituted further. A ring may be formed by linking the substituents.

Y is preferably an aromatic group, more preferably an aromatic hydrocarbon group, and further preferably a phenyl group which may have a substituent or a naphthyl group. Specific examples of the compound represented by Formula (A) are listed bellow. The invention is not limited to these compounds.

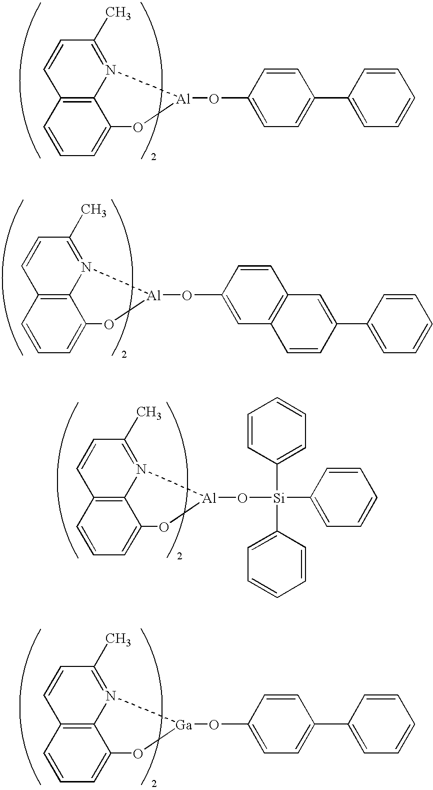

The thickness of the hole blocking layer is preferably 1 to 50 nm and further preferably 2 to 30 nm.

### <Protective Layer>

In the invention, the whole organic EL element may be protected by a protective layer.

The material included in the protective layer may have a function to deter a substance from entering into the element that will promote the deterioration of the element such as moisture and oxygen.

Specific examples of the material included in the protective layer include metals such as In, Sn, Pb, Au, Cu, Ag, Al, Ti, and Ni, metal oxides such as MgO, SiO, SiO₂, Al₂O₃, GeO, NiO, CaO, BaO, Fe₂O₃, Y₂O₃, and TiO₂, metal nitrides such as SiNₓ and SiNₓO_{y}, metal fluorides such as MgF₂, LiF, AlF₃, and CaF₂, polyethylene, polypropylene, poly(methyl methacrylate), polyimide, polyurea, polytetrafluoroethylene, polychlorotrifluoroethylene, polydichlorodifluoroethylene, a copolymer of chlorotrifuoroethylene and dichlorofluoroethylene, a copolymer obtained by copolymerizing a mixture of monomers including tetrafluoroethylene and at least one kind of comonomer, fluorine-containing copolymers having a ring structure in the main chain of the copolymer, water-absorbent substances having water absorption of 1% or more, and water absorptive materials having water absorption of 0.1% or less.

The method of forming the protective layer is not particularly limited and for example, a vacuum deposition method, a sputtering method, a reactive sputtering method, a MBE (Molecular Beam Epitaxy) method, a cluster ion beam method, an ion plating method, a plasma polymerization (a high-frequency excitation ion plating method), a plasma CVD method, a laser CVD method, a thermal CVD method, a gas source CVD method, a coating method, a printing method, and a transfer method can be applied.

### <Sealing>

In the organic electroluminescent element of the invention, the entire element may be sealed using a sealed vessel.

The moisture absorbent or inert liquid may be sealed in the space between the sealed vessel and the luminescent element. Although the moisture absorbent is not particularly limited, examples include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, a molecular sieve, zeolite, and magnesium oxide. Although the inert liquid is not particularly limited, examples are paraffin, fluidized paraffin, fluorine based solvents such as perfluoroalkane, perfluoroamine, and perfluoroether, chlorine based solvents, and silicone oils.

In the organic electroluminescent element of the invention, luminescence can be obtained by applying a DC (may include an AC component as occasion demands) voltage (normally, 2V to 15V) or a DC current.

The driving method described in JP-A Nos. 2-148687, 6-301355, 5-29080, 7-134558, 8-234685, and 8-241047, Japanese Patent No. 2784615, and U.S. Pat. Nos. 5,828,429 and 6,023,308 may be applied as the driving method of the organic electroluminescent element of the invention.

The organic EL element of the invention can be desirably used in a display element, a display, a backlight, electrophotography, an illuminating light source, a recording light source, an exposing light source, a reading light source, a mark, a signboard, an interior light, an optical communication, etc.

### EXAMPLES

The invention is explained specifically by listing examples as follows. However, the invention is not limited to these examples.

### Example 1

An ITO thin film (0.2 μm thickness) as a transparent anode was formed on a 2.5 cm square glass substrate of 0.5 mm thickness by DC magnetron sputtering (conditions: substrate temperature of 100° C., oxygen pressure of 1×10⁻³ Pa) using an ITO target in which the content ratio of In₂O₃ was 95% by mass. The surface resistance of the ITO thin film was 10 Ω/sq.

After the substrate on which the transparent anode was formed was placed in a cleaning container and cleaned with IPA, UV-ozone treatment was performed on the substrate for 30 minutes. Copper phthalocyanine (CuPC) was deposited on the transparent anode by a vacuum deposition method at a speed of 0.5 nm/sec, and a hole injection layer of 10 nm thickness was formed.

On the hole injection layer, α-NPD((N,N′-di-α-naphtyl-N,N′-diphenyl)-benzidine) was deposited by a vacuum deposition at a speed of 0.5 nm/sec, and a hole transport layer of 40 nm thickness was formed.

On the hole transport layer, the example compound (1-1) as a host material in the luminescent layer and the example compound (3-1) as a luminescent material (dopant) in the luminescent layer were co-deposited at a ratio of 100/8 by a vacuum deposition method, and a luminescent layer of 40 nm thickness was obtained.

Alq₃ was deposited on the luminescent layer by a vacuum deposition method at a speed of 0.2 nm/sec, and an electron transport layer of 20 nm thickness was formed.

A patterned mask (a mask in which the luminescent area is 2 mm×2 mm) was placed on the luminescent layer and lithium fluoride was deposited at 1 nm with vacuum deposition. Aluminum was deposited on this by vacuum deposition, and a cathode of 0.1 μm thickness was formed.

The obtained luminescent multi-layered body was placed in a glove box substituted with nitrogen gas, and sealed using a sealing can made of stainless steel equipped with a drying agent with an ultraviolet-curing adhesive (trade name: XNR5516HV, manufactured by Nagase Chiba), and a luminescent element of Example 1 was obtained.

The process from the deposition of copper phthalocyanine to the sealing was performed under a vacuum or a nitrogen atmosphere, and the manufacturing of the element was performed without exposure to the air. The layer configuration of the luminescent element of Example 1 is shown below.

ITO/CuPC/α-NPD/Example compound (1-1)+Example compound (3-1)/Alq₃/LiF/Al

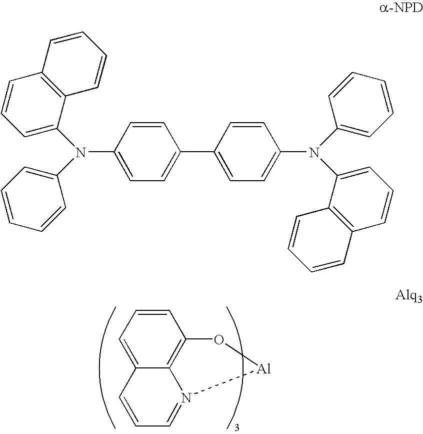

Using the obtained luminescent element of Example 1, the evaluation tests as follows were performed, and the luminescent characteristic and driving durability were measured and evaluated. The results are shown in Table 1.

### —Luminescent Characteristic—

The luminescence of the luminescent element was measured by measuring the luminescence of the emitted light from the luminescent element when a DC voltage of 8V was applied using a Source-Measure Unit Model 2400 manufactured by KEITHLEY with a luminescence meter SR-3 manufactured by Topcon, and treated as the luminescent characteristic.

### —Driving Durability—

A continuous driving test at a constant electric current was performed on the luminescent element under the condition of an initial luminescence of 1000 cd/m², and the time when the luminescence was reduced by half was treated as a luminescence half-time T (1/2).

### Example 2

A luminescent element of Example 2 was obtained in the same manner as in Example 1 except that the film thickness of the luminescent layer was made to be 30 nm and BAlq was deposited with a thickness of 10 nm at a speed of 0.05 nm/sec by a vacuum deposition method as a hole blocking layer between the luminescent layer and the electron transport layer in Example 1, and the same evaluation tests as in Example 1 were performed. The results are shown in Table 1.

The layer configuration of the luminescent element of Example 2 is shown as follows.

ITO/CuPC/α-NPD/Example compound (1-1)+Example compound (3-1)/BAlq/Alq₃/LiF/Al

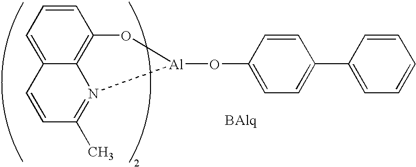

### Example 3

A luminescent element of Example 3 was obtained in the same manner as in Example 2 except that the example compound (3-1) used as a luminescent material in the luminescent layer in Example 2 was replaced with the example compound (3-2), and the same evaluation tests as in Example 1 were performed. The results are shown in Table 1. The layer configuration of the luminescent element of Example 3 is shown below.

ITO/CuPC/α-NPD/Example compound (1-1)+Example compound (3-2)/BAlq/Alq₃/LiF/Al

### Example 4

A luminescent element of Example 4 was obtained in the same manner as in Example 2 except that the example compound (3-1) used as a luminescent material in the luminescent layer in Example 2 was replaced with the example compound (4-1), and the same evaluation tests as in Example 1 were performed. The results are shown in Table 1.

The layer configuration of the luminescent element of Example 4 is shown below.

ITO/CuPC/α-NPD/Example compound (1-1)+Example compound (4-1)/BAlq/Alq₃/LiF/Al

### Example 5

A luminescent element of Example 5 was obtained in the same manner as in Example 2 except that the example compound (1-1) used as a host material in the luminescent layer in Example 2 was replaced with the example compound (2-1), and the example compound (3-1) used as a luminescent material was replaced with the example compound (4-3), and the same evaluation tests as in Example 1 were performed. The results are shown in Table 1.

The layer configuration of the luminescent element of Example 5 is shown below.

ITO/CuPC/α-NPD/Example compound (2-1)+Example compound (4-3)/BAlq/Alq₃/LiF/Al

### Example 6

A luminescent element of Example 6 was obtained in the same manner as in Example 3 except that the example compound (1-1) used as a host material in the luminescent layer in Example 3 was replaced with the example compound (1-3), and the same evaluation tests as in Example 1 were performed. The results are shown in Table 1.

The layer configuration of the luminescent element of Example 6 is shown below.

ITO/CuPC/α-NPD/Example compound (1-3)+Example compound (3-2)/BAlq/Alq₃/LiF/Al

### Example 7

A luminescent element in Example 7 was obtained in the same manner as in Example 3 except that the example compound (1-1) used as a host material in the luminescent layer in Example 3 was replaced with the example compound (2-1), and the same evaluation tests as in Example 1 were performed. The results are shown in Table 1.

The layer configuration of the luminescent element of Example 7 is shown below.

ITO/CuPC/α-NPD/Example compound (2-1)+Example compound (3-2)/BAlq/Alq₃/LiF/Al

### Comparative Example 1

A luminescent element of Comparative Example 1 was obtained in the same manner as in Example 3 except that the example compound (1-1) used as a host material in the luminescent layer in Example 3 was replaced with CBP, and the same evaluation tests as in Example 1 were performed. The results are shown in Table 1.

The layer configuration of the luminescent element of Comparative Example 1 is shown below.

ITO/CuPC/α-NPD/CBP+Example compound (3-2)/BAlq/Alq₃/LiF/Al

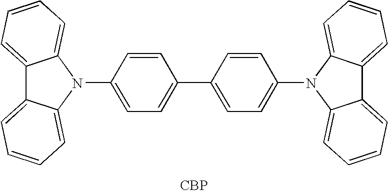

### Comparative Example 2

A luminescent element of Comparative Example 2 was obtained in the same manner as in Example 1 except that the luminescent layer was formed using only the example compound (1-1) in Example 1, and the same evaluation tests as in Example 1 were performed. The results are shown in Table 1.

The layer configuration of the luminescent element of Comparative Example 2 is shown as follows.

ITO/CuPC/α-NPD/Example compound (1-1)/Alq₃/LiF/Al

TABLE 1

| | | Driving durability |
|---|---|---|
| | Luminescent characteristic | Luminescence |
| | Luminescence | half-time (initial |
| | when 8 V is applied | luminescence 1000 cd/m²) |
| Example 1 | 480 cd/m² | 230 hours |
| Example 2 | 390 cd/m² | 460 hours |
| Example 3 | 280 cd/m² | 250 hours |
| Example 4 | 550 cd/m² | 710 hours |
| Example 5 | 180 cd/m² | 210 hours |
| Example 6 | 210 cd/m² | 200 hours |
| Example 7 | 350 cd/m² | 180 hours |
| Comparative | 30 cd/m² | 60 hours |
| example 1 | | |
| Comparative | 80 cd/m² | 70 hours |
| example 2 | | |

As shown in Table 1, the organic electroluminescent element which exhibits excellent luminescent characteristic of emitting light and driving durability can be obtained by the invention.

All publications, patent applications, and technical standards mentioned in this specification are herein incorporated by reference to the same extent as if each individual publication, patent application, or technical standard was specifically and individually indication to be incorporated by reference.

What is claimed is:

1. An organic electroluminescent element comprising:
a pair of electrodes; and
one or more organic compound layers disposed between the pair of electrodes and including at least one luminescent layer,
wherein at least one layer of the organic compound layers includes at least one compound selected from the group consisting of a trispyrenylbenzene derivative and a dipyrenylbenzene derivative and at least one compound selected from a tetraphenylpyrene derivative and a tetraminopyrene derivative.

2. The organic electroluminescent element of claim 1, wherein at least one layer of the organic compound layers includes the trispyrenylbenzene derivative, and the trispyrenylbenzene derivative is a compound represented by the following Formula (1): 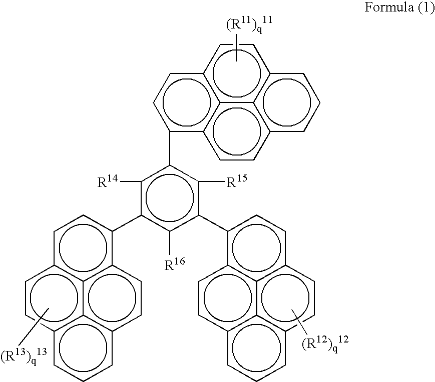
wherein, in Formula (1), R¹¹, R¹², and R¹³ each independently represent a substituent; R¹⁴, R¹⁵, and R¹⁶ each independently represent ahydrogenatomora substituent; and q¹¹, q¹², and q¹³ each independently represent an integer from 0 to 9.

3. The organic electroluminescent element of claim 1, wherein at least one layer of the organic compound layers includes the dipyrenylbenzene derivative, and the dipyrenylbenzene derivative is a compound represented by the following Formula (2): 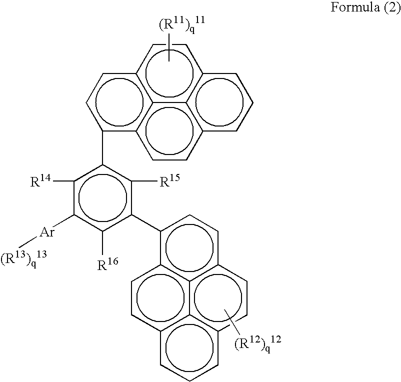
wherein, in Formula (2), R¹¹, R¹², and R¹³ each independently represent a substituent;
R¹⁴, R¹⁵, and R¹⁶ each independently represent a hydrogen atom or a substituent; q¹¹, q¹², and q¹³ each independently represent an integer from 0 to 9; and Ar represents an arylene group.

4. The organic electroluminescent element of claim 1, wherein λₘₐₓ of the fluorescence spectrum (maximum luminescent wavelength) of at least one compound selected from the group consisting of the trispyrenylbenzene derivative and the dipyrenylbenzene derivative is in the range of 400 to 500 nm.

5. The organic electroluminescent element of claim 1, wherein at least one layer of the organic compound layers includes the tetraphenylpyrene derivative, and the tetraphenylpyrene derivative is a compound represented by the following Formula (a): 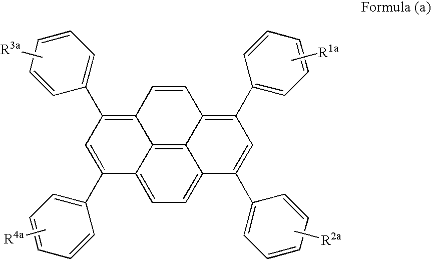
wherein, in Formula (a), R^{1a}, R^{2a}, R^{3a}, and R^{4a} each independently represent a hydrogen atom or a substituent.

6. The organic electroluminescent element of claim 1, wherein at least one layer of the organic compound layers includes the tetraphenylpyrene derivative, and the tetraphenylpyrene derivative is a compound represented by the following Formula (b): 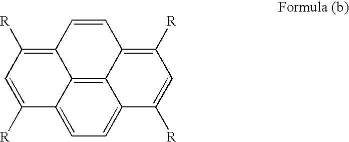
wherein, in Formula (b), R represents a group represented by the following formula: 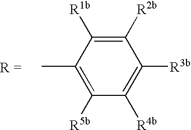
wherein R^{1b} to R^{5b} each independently represent a hydrogen atom or a substituent; and at least one of R^{1b} to R^{5b} is a substituted or unsubstituted phenyl group.

7. The organic electroluminescent element of claim 1, wherein at least one layer of the organic compound layers includes the tetraphenylpyrene derivative, and the tetraphenylpyrene derivative is a compound represented by the following Formula (c): 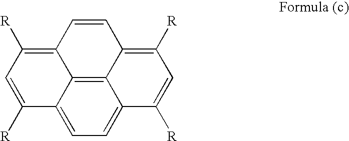
wherein, in Formula (c), R represents a group represented by the following formula: 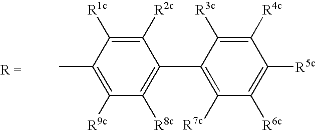
wherein R^{1c} to R^{9c} each independently represent a hydrogen atom or a substituent.

8. The organic electroluminescent element of claim 1, wherein at least one layer of the organic compound layers includes the tetraphenylpyrene derivative, and the tetraphenylpyrene derivative is a compound represented by the following Formula (d): 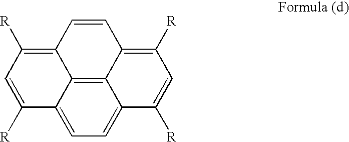
wherein, in Formula (d), R represents a group represented by the following formula: 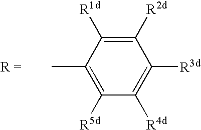
wherein R^{1d} to R^{5d} each independently represent a hydrogen atom or a substituent; and at least one of R^{1d} to R^{5d} is a group represented by the following formula: 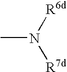
wherein R^{6d} and R^{7d} each independently represent a hydrogen atom or a substituent.

9. The organic electroluminescent element of claim 1, wherein at least one layer of the organic compound layers includes the tetraminopyrene derivative, and the tetraminopyrene derivative is a compound represented by the following Formula (e): 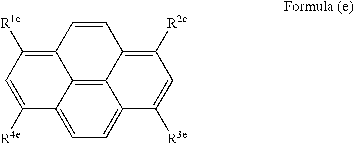
wherein, in Formula (e), R^{1e} to R^{4e} each independently represent a group represented by the following formula: 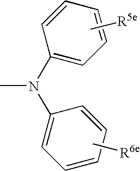
wherein R^{5e} and R^{6e} each independently represent a hydrogen atom or an alkyl group.

10. The organic electroluminescent element of claim 1, wherein at least one layer of the organic compound layers includes the tetraminopyrene derivative, and the tetraminopyrene derivative is a compound represented by the following Formula (f): 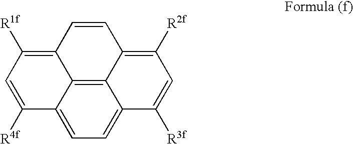
wherein, in Formula (f), R^{1f} to R^{4f} each independently represent a group represented by the following formula: 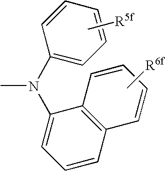
wherein R^{5f} and R^{6f} each independently represent a hydrogen atom or an alkyl group.

11. The organic electroluminescent element of claim 1, wherein at least one layer of the organic compound layers includes the tetraminopyrene derivative, and the tetraminopyrene derivative is a compound represented by the following Formula (g): 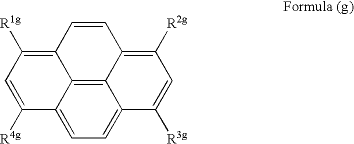
wherein, in Formula (g), R^{1g} to R^{4g} each independently represent a group represented by the following formula: 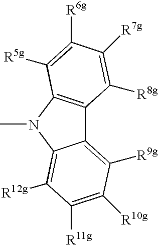
wherein R^{5g} to R^{12g} each independently represent a hydrogen atom, an alkyl group, a substituted alkyl group, an aryl group, or a substituted aryl group.

12. The organic electroluminescent element of claim 1, wherein the content ratio by mass of the at least one compound selected from the group consisting of the trispyrenylbenzene derivative and the dipyrenylbenzene derivative to the at least one compound selected from the group consisting of the tetraphenylpyrene derivative and the tetraminopyrene derivative in one layer of the organic compound layers is in the range of from 100:0.1 to 100:30.

13. The organic electroluminescent element of claim 1, wherein the luminescent layer includes the at least one compound selected from group consisting of the trispyrenylbenzene derivative and the dipyrenylbenzene derivative and the at least one compound selected from the group consisting of the tetraphenylpyrene derivative and the tetraminopyrene derivative.

14. The organic electroluminescent element of claim 13, wherein the at least one compound selected from the group consisting of the trispyrenylbenzene derivative and the dipyrenylbenzene derivative is included as a host material, and the at least one compound selected from the group consisting of the tetraphenylpyrene derivative and the tetraminopyrene derivative is included as a dopant.
